(19) United States
(12) Patent Application Publication
(10) Pub. No.: US 2011/0273854 A1
(43) Pub. Date: Nov. 10, 2011

(54) Magnetic Field Sensor

(76) Inventors: Klaus-Juergen Wagner, Grossbottwar (DE); Stefan Leopold, Kirchheim Am Neckar (DE)

(21) Appl. No.: 13/102,269

(22) Filed: May 6, 2011

(30) Foreign Application Priority Data
May 10, 2010 (DE) 10 2010 020 119.7

(51) Int. Cl. H05K 5/00; H05K 7/04

(52) U.S. Cl. 361/752; 361/809

(57) ABSTRACT

The invention relates to a magnetic field sensor comprising a housing which includes a plug and encloses sensor electronics. According to the invention, the housing comprises a two-pieced housing composed of a housing top part, which has a single opening, and a housing base which closes the opening, and out of which the contact pins of the plug extend, and which carries the sensor electronics.

The invention relates to a magnetic field sensor comprising a housing which includes a plug and encloses sensor electronics. Such sensors are used in motor vehicles, e.g. to measure linear displacement or the angular position of a magnetic position sensor.

The problem addressed by the present invention is that of demonstrating a way to more economically manufacture a magnetic field sensor suitable for use in motor vehicles.

This problem is solved by a magnetic field sensor having the features indicated in claim 1. Advantageous refinements of the invention are the subject matter of dependent claims.

### SUMMARY OF THE INVENTION

A magnetic field sensor according to the invention comprises a two-pieced housing composed of a housing top part, which has a single opening, and a housing base which closes the opening. Contact pins of a plug, i.e. a male connector, extend outwardly from the housing base which also contains the sensor electronics.

A magnetic field sensor according to the invention can be manufactured at low cost since the electronics can be preinstalled on the housing base, and then only two more parts need to be joined, namely the housing top part and the housing base comprising the sensor electronics and the contact pins. Particularly advantageously, the sensor electronics enclosed by the housing can be protected against harmful environmental influences, such as splash water and the like, in a simple manner by the combination of a housing top part, which has a single opening, and a housing base which closes the opening. Advantageously, complex measures such as sealing rings or filling the housing interior with an electrically insulating protective compound can be omitted.

The sensor electronics of a magnetic field sensor according to the invention can contain e.g. a Hall sensor or a resistor element, the electrical resistance of which changes depending on a magnetic field. Materials for such resistor elements are known per the keyword “giant magnetic resistance”. Other methods for magnetic field measurement, such as coils or the like, can also be used for a magnetic field sensor according to the invention.

The present invention furthermore relates to a system composed of such a magnetic field sensor and a female connector which fits the plug of the magnetic field sensor and can be inserted into a section of the housing top part of the magnetic field sensor. When the magnetic field sensor is connected to the female connector, the female connector provides an additional seal which also hinders splash water or the like from entering the interior space of the magnetic field sensor. This is possible because the female connector encloses the housing top part of the magnetic field sensor inserted therein. The female connector preferably comprises a sealing lip which rests on the circumference of the housing top part.

According to an advantageous refinement of the invention, the housing top part comprises on the outer side thereof at least one holding element for holding the female connector. Snap-in projections or other snap-in elements which hold, in a form-fit manner, a female connector enclosing the outer side of the housing are particularly suitable, for example.

According to a further advantageous refinement of the invention, the sensor electronics are disposed on a printed circuit board which is mounted on the housing base. In this manner the sensor electronics can be advantageously connected to the housing base to form an easily handled assembly which then needs only to be joined to the housing top part. The contact pins of the plug can be pressed into openings in the printed circuit board, or they can be soldered to the printed circuit board or connected using connecting wires.

Preferably the housing base grips the printed circuit board on opposite edges. It is thereby easier to fasten the printed circuit board to the housing base. As an alternative or in addition thereto, the housing base can be provided with raised areas which engage in positioning holes in the printed circuit board.

According to a further advantageous development of the invention, the housing base is pressed into the housing top part. A connection, which is resistant to splash water, between the housing base and the housing top part can therefore be obtained in a simple manner. To fasten the housing base in the housing top part in a particularly reliable manner and in a defined position, the housing base can be snapped into position with the housing top part. The housing base can be clipped into the housing top part, for example.

### BRIEF DESCRIPTION OF THE DRAWINGS

Further details and advantages of the invention are explained using an embodiment, with reference to the attached drawings. In the drawings:

FIG. 1: shows a magnetic field sensor according to the invention, in an exploded view;

FIG. 2: shows a longitudinal cross section of the magnet field sensor; and

FIG. 3 shows a longitudinal cross section of the magnet field sensor and a matching connector.

### DETAILED DESCRIPTION

The magnetic field sensor shown comprises a two-pieced housing, i.e. a housing composed of only two pieces. The two-pieced housing is formed of a housing top part 1, which has a single opening, and a housing base 2 which closes the opening. Housing base 2 comprises contact pins 3 of a plug. Housing top part 1 is also used as the plug housing and can comprise guides for a female connector. Housing top part 1 and housing base 2 are made of plastics, e.g. by injection molding.

Housing base 2 comprises a printed circuit board 4 on which sensor electronics 4a for magnetic field measurement are disposed. Sensor electronics 4a can comprise a Hall sensor, for example. Housing base 2 grips printed circuit board 4 on opposite edges. In the embodiment shown, opposite lateral surfaces of printed circuit board 4 are covered by housing base 2. Housing base 2 therefore comprises a recess into which printed circuit board 4 is inserted. When printed circuit board 4 is inserted, contact pins 3 of housing base 2 can be pressed into printed circuit board 4. It is also possible to connect contact pins 3 to printed circuit board 4 by soldering. The housing base can be injection molded around the contact pins 3. It is also possible to press the contact pins into housing base 2.

To install the magnetic field sensor, housing base 2 is pressed into housing top part 1 and snaps into a defined position in the interior of housing top part 1.

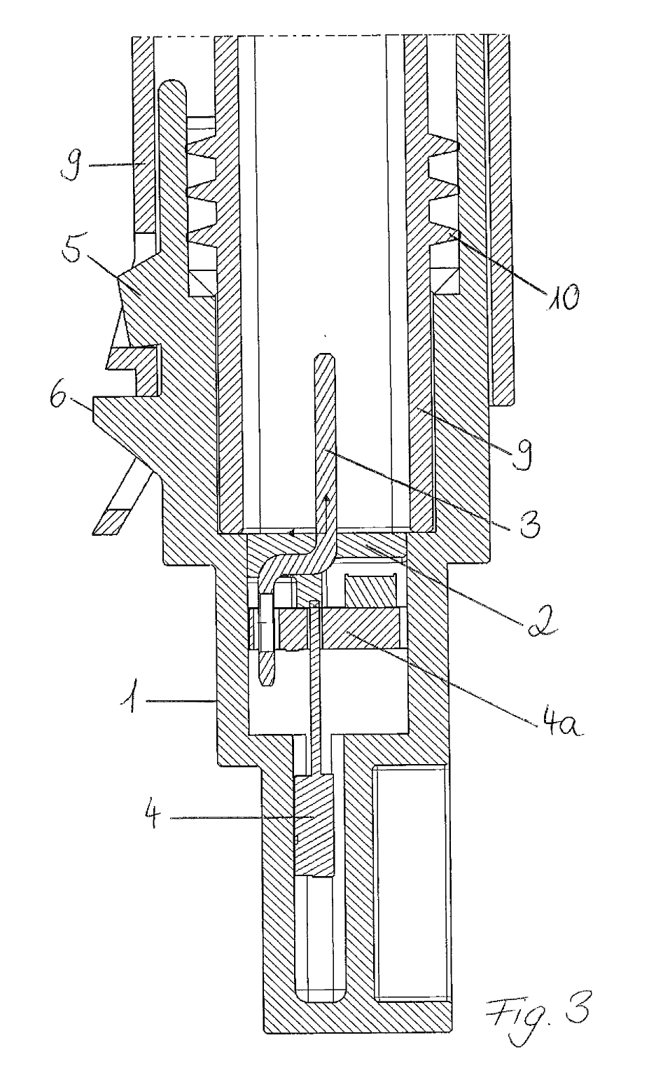

Housing top part 1 can comprise, on the outer side thereof, one or more holding elements 5 for holding a female connector 9 shown schematically in FIG. 3. As shown in the sectional view in FIG. 2 in particular, such a holding element 5 can be designed as a snap-in projection, for example. In addition, housing top part 1 can comprise, on first side thereof, a stop element 6 which abuts the female connector 9 when the magnetic field sensor is inserted therein. The female connector then encloses housing top part 1 around the circumference, thereby providing an additional seal. To improve the seal further, the female connector 9 can comprise a circumferential sealing lip 10. FIG. 3 shows that an inner part of the female connector 9 is surrounded by the housing part 1 and that an outer part of the female connector 9 surrounds a section of the housing 1.

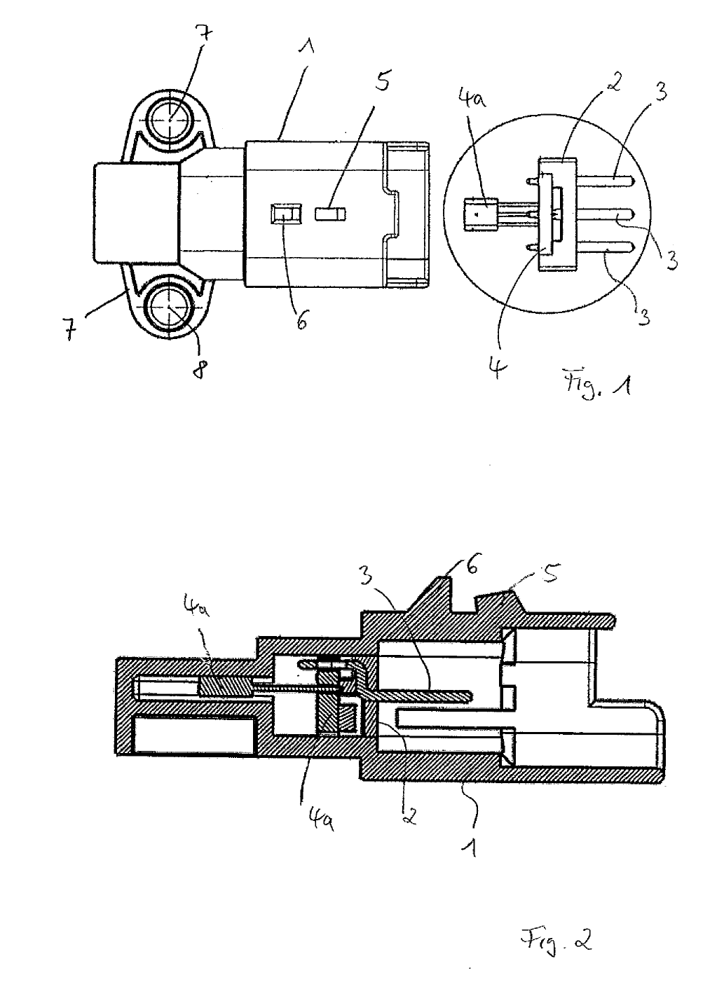

As shown in FIG. 1 in particular, housing top part 1 can comprise a flange 6 which can be used to install the magnetic field sensor in a motor vehicle, for example. In the embodiment shown, flange 7 comprises an eyelet 8 on each of the opposite sides of housing top part 1.

### REFERENCE NUMERALS

1 Housing top part
2 Housing base
3 Contact pin
4 Printed circuit board
4a Sensor electronics
5 Holding element
6 Stop element
7 Flange
8 Eyelet

What is claimed is:

1. A magnetic field sensor comprising a housing for enclosing sensor electronics and including a plug having contact pins, the housing comprising a housing top part, having a single opening, and a housing base for closing the opening, and carrying the sensor electronics, said contact pins of the plug extending from the housing base.

2. The magnetic field sensor according to claim 1, wherein the sensor electronics are disposed on a printed circuit board which is mounted on the housing base.

3. The magnetic field sensor according to claim 2, wherein the housing base grips the printed circuit board on opposite edges.

4. The magnetic field sensor according to claim 1, wherein lateral surfaces of the printed circuit board face a wall of the housing top part.

5. The magnetic field sensor according to claim 1, wherein the sensor electronics are disposed at least in part on a front side of the printed circuit board, and a back side of the printed circuit board faces the housing base.

6. The magnetic field sensor according to claim 1, wherein the printed circuit board is oriented perpendicularly to the direction of the contact pins.

7. The magnetic field sensor according to claim 2, wherein the housing base covers opposite lateral surfaces of the printed circuit board.

8. The magnetic field sensor according to claim 1, wherein the housing top part comprises, on the outer side thereof, a holding element for holding a mating connector.

9. The magnetic field sensor according to claim 1, wherein the housing base is pressed into the housing top part.

10. The magnetic field sensor according to claim 1, wherein the housing base is snapped into position with the housing top part.

11. The magnetic field sensor according to claim 1, wherein the housing top part comprises a flange for installing the sensor in a motor vehicle.

12. The magnetic field sensor according to claim 11, wherein the flange comprises an eyelet on two sides of the housing top part.

13. The magnetic field sensor according to claim 1, wherein the housing top part forms a housing of the plug.

14. The magnetic field sensor according to claim 1, wherein the housing base comprises a recess into which the printed circuit board is inserted.

15. The magnetic field sensor according to claim 1, wherein the housing top part is a cup-shaped injection-molded part.

16. A system composed of a magnetic field sensor according to claim 1, and a mating connector which fits the plug of the magnetic field sensor, and into which a section of the housing top part of the magnetic field sensor can be inserted.

17. The system according to claim 16, wherein the mating connector comprises a sealing lip.
